(19) United States
(12) Patent Application Publication
(10) Pub. No.: US 2024/0419761 A1
(43) Pub. Date: Dec. 19, 2024

(54) EFFICIENT COMBINATORIAL OPTIMIZATION BY QUANTUM-INSPIRED PARALLEL ANNEALING IN ANALOGUE MEMRISTOR CROSSBAR

(71) Applicant: The University of Hong Kong, Hong Kong (HK)

(72) Inventors: Can LI, Hong Kong (HK); Mingrui JIANG, Hong Kong (HK)

(21) Appl. No.: 18/740,554

(22) Filed: Jun. 12, 2024

Related U.S. Application Data
(60) Provisional application No. 63/508,260, filed on Jun. 14, 2023.

(51) Int. Cl. G06F 17/18; G11C 13/00

(52) U.S. Cl. CPC G06F 17/18; G11C 13/0002

(57) ABSTRACT

A quantum-inspired parallel annealing method that enables full parallelism and improves solution quality, resulting in significant speed and energy improvement when implemented in analog memristor crossbars. Tasks are experimentally solved, including unweighted and weighted Max-Cut and traveling salesman problem using an integrated memristor chip. The method claimed herewith effective exploits the natural parallelism, analog conductance states and all-to-all connection provided by memristor technology, and therefore demonstrates significant improvements in time- and energy-efficiency compared to previous simulated annealing and Ising machine implemented on other technologies, having a large potential for solving complex optimization problems with greater efficiency.

### CROSS-REFERENCE TO RELATED APPLICATIONS

The present application claims priority from U.S. provisional patent application Ser. No. 63/508,260 filed Jun. 14, 2023, and the disclosures of which are incorporated by reference in their entireties.

### FIELD OF THE INVENTION

The present invention generally relates to the field of combinatorial optimization. More specifically the present invention relates to providing an alternative with higher efficiency in solving the combinatorial optimization problem through quantum-inspired parallel annealing in analog memristor crossbar.

### BACKGROUND OF THE INVENTION

Combinatorial optimization problems (COPs) are ubiquitous in social life and industry, with diverse applications in fields including, but not limited to, computer science, engineering, chemistry, logistics and economics.

Unfortunately, exact solutions are notoriously challenging to obtain due to the combinatorial explosion that occurs as problem size increases. Consequently, special-purpose hardware such as Ising machines are increasingly sought after to efficiently solve COPs by mapping them to the Ising model, a statistical model that describes a physical system comprising spins that interact with one another, which tends to evolve into the lowest system energy.

Although classical computers can emulate the process, their efficiency is significantly limited due to their digital and serial nature and the property of separated memory and processing units.

To overcome these limitations, researchers have explored various analog technologies including superconducting qubits, coherent lights, CMOS oscillators, nano oscillators and memristors-based analog Ising machines. Among these, memristor-based machines offer particular promise with their speed and energy efficiency, natural all-to-all connections, and compatibility with electronic computing ecosystems.

Nonetheless, existing memristor-based demonstrations have not fully exploited the massive parallelism and analog storage/processing features of memristor crossbar arrays. Previous works mainly relied on simulated annealing and its variants to obtain the optimal solution and thus were limited to the serial updating nature of simulated annealing. Consequently, in these implementations, the memristor crossbar performed only one vector-vector dot-product operation at a time, rather than a vector-matrix multiplication, resulting in a huge iste of the natural parallelism provided by the memristor crossbar array.

Adiabatic annealing as another annealing method with solid theoretical background which has successfully implemented in quantum systems, recently has demonstrated effectiveness with classical memristor-based platforms, shedding light on possible parallel updates.

However, in this pioneer work, simulated annealing is still required in the solving process in addition to adiabatic annealing and thus does not get rid of its serial updating limitation. Moreover, most previous works only demonstrated binarized memristor conductance, instead of analog values to represent arbitrary coupling strength in representing the problem, limiting the complexity of the problem that it can solve.

### SUMMARY OF THE INVENTION

In view of the existing challenges in the field, it is an objective of the present invention to provide a solution with a higher efficiency in solving the combinatorial optimization problems through simulating quantum adiabatic annealing using a classical analog memristor crossbar.

In accordance with a first aspect of the present invention, a quantum-inspired parallel annealing processor for analysing and solving combinatorial optimization problems with increased efficiency is provided herewith, comprising:
memristor crossbar arrays;
drivers;
multiplexers;
transimpedance amplifiers;
analog-to-digital converters; and
digital logics;
wherein the crossbar arrays can be formed in a one-transistor one-memristor configuration or alternative configurations.

In accordance with one embodiment of the present invention, the solving of the combinatorial optimization problems comprises representing the spin configuration as discrete values; utilizing an analog variable to depict the intermediate spin states; and implementing a time-dependent system Hamiltonian; and employing a straight-through estimator algorithm to update the analog intermediate spin variable based on the system Hamiltonian's gradient computed from the actual spin configuration.

In accordance with another embodiment of present invention, the Ising couplings between each spin pair are stored as analog conductance values in the memristor crossbar to enable single-step in situ calculation of the Ising Hamiltonian's gradient.

### BRIEF DESCRIPTIONS OF DRAWINGS

For a better understanding of the various embodiments described herein and to show more clearly how these various embodiments may be carried into effect, reference will be made, by way of example, to the accompanying drawings, which show at least one example embodiment, and which are now described.

FIG. 1 shows the key properties of quantum-inspired parallel annealing and its difference with simulated thermal annealing. Simulated thermal annealing, also known as simulated annealing, has a serial updating nature and differs from the quantum-inspired parallel annealing of the present invention in terms of annealing strategy, updating scheme and hardware implementation methods.

FIGS. 2A to 2F show an experimental demonstration of QPA in memristor crossbar array. FIG. 2A provides a schematic of experiment set-up. A general-purpose computer controls the integrated memristor chip, which stores the Ising coupling matrix values and computes the gradient in the analog domain, and implements the part of spin updating in the digital domain. On the right is the optical image of the integrated memristor chip, which consists of multiple 64×64 one-transistor-one-memristor (1T1M) arrays with necessary peripheral circuits including drivers, multiplexers (MUXs), transimpedance amplifiers (TIAs) and analog-to-digital converters (ADCs) FIG. 2B shows Ising coupling matrix of a target 64-node 50%-density Max-Cut problem, and FIG. 2C experimental read-out conductance value after programming the Ising coupling onto the memristor crossbar array. “0”s are programmed to target 0 uS, while “−1”s target 150 μS. FIGS. 2D and 2E are performance comparison of QPA, SA and DHNN in terms of success probability (FIG. 2D) and average solution gap (solution gap=optimal maximum cut-obtained cut) across different total iterations (FIG. 2E). One iteration represents one attempt to update the spins. The blue dashed line shows the simulation result of QPA, which shows strong agreement with experiment data. Each data point is calculated based on 100 different trials from random initial states. FIG. 2F illustrates the relationship between success probability and problem density for different techniques including the QPA of the present invention, SA, CIM and D-Wave. The shaded area in the plot shows interquartile range (25%-75%). For each problem density, 20 randomly generated problem instances are solved. 1000 trials are conducted for each problem instance to calculate the success probability. For QPA and SA, the annealing time is 1000 iterations, which takes 1,000 μs if assuming each iteration takes 1 μs. For CIM and D-Wave, the annealing time is also 1,000 μs.

FIGS. 3A to 3H shows the weighted Max-Cut problem with analog conductance values for Ising coupling. FIG. 3A shows the normalized Ising coupling matrix (−J/max (−J)) of a randomly generated 64-node all-to-all connected Max-Cut problem. Each connection strength is randomly selected from a 16-bit integer (0 to 65,535). FIG. 3B shows the experimental read-out conductance matrix after programming the Ising coupling to the memristor crossbar array, with the maximum coupling strength programmed targeting 150 μS. FIG. 3C illustrates the distribution of programming error (the difference between the experimental read-out conductance and the target conductance), with the dash line showing the Gaussian distribution fitting with a mean of 0.29 μS and a standard deviation of 2.36 μS. FIG. 3D illustrates the distribution of computing error (the difference between the experimental result and the expected value) of the analog memristor crossbar, with the dashed line indicates a Gaussian distribution with a mean of 0.01 and a standard deviation of 0.57. 1000 random input vectors with each entry randomly taken from either +1 or −1 are generated for the vector-matrix multiplication to get a distribution. The expected value is calculated by software with full floating-point precision. FIG. 3E illustrates the calculated cut-values during the solving process with QPA, DHNN and SA schemes. The goal is to get a maximum possible cut value. The cut-values shown here is normalized by dividing the obtained cut value by the optimal maximum cut. The light color lines represent 100 different trials from random initial spin configurations, and the dark color lines represent the average cut value. The annealing time for all three methods is 1000 total iterations. FIG. 3F shows the corresponding solution cut distribution of three methods. FIG. 3G shows the impact of conductance variations of memristors. For each data point, 20 randomly generated problem instances with connection strength randomly taken from 16-bit integers are solved 1000 times with random initial spin configuration. The blue lines with square, round and pentagon markers represent the success probability to optimal maximum cut, 99.9% of the maximum cut and 99.5% of the maximum cut, respectively. FIG. 3H illustrates the scaling trend of time-to-solution (TTS) with problem size. For each problem size, 20 randomly generated problem instances with connection strength randomly taken from 16-bit integers are solved 1000 times with random initial spin configuration. The shaded area in the plot shows interquartile range, the square marker indicates the median, and the dashed line shows the fit of TTS=ae^{b\sqrt{N}}.

FIGS. 4A to 4E illustrates the travelling salesman problem. FIG. 4A presents a target N-city traveling salesman problem, with solid circles marking the location of Hong Kong, London, Johannesburg, Tokyo, Dubai, Sao Paulo, Sydney, Singapore, and New York, respectively. The goal is to find a route that travels all cities once with the minimum distance. FIG. 4B illustrates the representation of the visiting order by an (N−1)×(N−1) matrix, with rows representing the city and columns representing the order of visit. Each row and column can have only one element set to one, representing a valid visiting order. City 1 (Hong Kong in this case) is always chosen as the first city to be visited. The matrix in the plot represents the example valid visiting order shown in FIG. 4A, which is Hong Kong>Singapore>Dubai>London>New York>Sao Paulo>Johannesburg>Sydney>Tokyo>Hong Kong. FIG. 4C shows the normalized Ising coupling matrix of the target problem (upper), and the experimental read-out conductance value after programming the Ising coupling to the memristor crossbar array (lower) respectively. The maximum coupling strength is programmed targeting 150 μS. FIG. 4D illustrates the evolution of the Ising Hamiltonian during the solving process. The dark color lines represent the average cut value over 100 different trails (light-colored lines) from random initial states. 1000 total iterations are used for all three methods. FIG. 4E shows a comparison of solution quality obtained by QPA, SA and DHNN. Three performance metrics are compared: number of valid tours, minimum distance and average distance. The number of valid tours represents the number of solutions that obey the constraints of each city should be visited and visited once (the larger the better). Minimum distance refers to the shortest traveling distance among 100 trials, and average distance represents the mean value of the traveling distance of valid tours (the smaller the better).

FIG. 5 shows the average success probability of different Hᵢₙᵢₜᵢₐₗ functions with different total iteration numbers. The curves with different color represent the case without Hᵢₙᵢₜᵢₐₗ, Hᵢₙᵢₜᵢₐₗ=Σᵢ₌₁^{N}|xᵢ|, Hᵢₙᵢₜᵢₐₗ=Σᵢ₌₁^{N} xᵢ, Hᵢₙᵢₜᵢₐₗ=Σᵢ₌₁^{N}xᵢ², Hᵢₙᵢₜᵢₐₗ=Σᵢ₌₁^{N}xᵢ³ and Hᵢₙᵢₜᵢₐₗ=Σᵢ₌₁^{N}xᵢ⁴, respectively. For each data point, 20 60-node 50%-density unweighted Max-Cut problem instances are solved. For each problem instance, 100 trials from random initial states are conducted for calculating the success probability. The data in the plot shows the average success probability over 20 problem instances. From the plot, it can be observed that symmetric functions including Σᵢ₌₁^{N}|xᵢ|, Σᵢ₌₁^{N}xᵢ², Σᵢ₌₁^{N}xᵢ⁴, perform better than asymmetric ones. Since they all have an easily found ground state obtained when all xᵢ=0. The success implementation of Σᵢ₌₁^{N}|xᵢ|, Σᵢ₌₁^{N}xᵢ² and Σᵢ₌₁^{N}xᵢ⁴ also implies that an arbitrary function can service as the initial Hamiltonian as long as its ground state can be easily solved. According to empirical observation, among these three functions, Σᵢ₌₁^{N}xᵢ² works the best, so it is chosen as the Hᵢₙᵢₜᵢₐₗ throughout the paper. Nonetheless, it is possible that there are other well-designed functions that can enhance performance, which requires further exploration.

FIGS. 6A and 6B shows the comparison of different updating techniques in unweighted Max-Cut problem. FIG. 6A shows the plot of average success probability against total iteration number. FIG. 6B shows the plot of average solution gap (defined as the difference between the solved cut value and the maximum cut value) against total iteration number. Five different updating techniques are compared: the original updating algorithm used in the paper (denoted as Baseline in the figure), one without discretizing the proxy spin value when calculating the gradient (STE), one without adding a momentum term, one without momentum and without STE, and one without clipping the proxy spin value to be between −1 and 1. For each data point in the plot, 20 60-node 50%-density unweighted Max-Cut problem instances are solved. For each problem instance, 100 trials from random initial states are conducted. From the plot, it can be seen that all three techniques, STE, momentum, and clipping, are essential to the performance.

The performance of the case without STE works as well as with STE when the total iteration number is small. However, with larger total iterations, the performance decreases. This is because without STE, during the whole solving process, the real binary spin is not involved, and the analog spin proxy cannot accurately reflect the result of the binary spin, which causes a mismatch [1]. Further updating on the analog spin proxy lacks the ability to lower the energy calculated by the binary spin. For the case without momentum, the system works like a greedy gradient descent algorithm, and the annealing fails. For this case, a local-minimum solution can be easily obtained, however, the global minimum can hardly be found. The role of momentum in the quantum-inspired annealing is not clear yet, but this might be related to the property of STE. Since the performance of vanilla stochastic gradient descent is much poorer than those ones with momentum in the field of binary neural network (BiNN) training. For the case without momentum and without STE, the annealing backs to work normally. The convergence speed is relatively slower than the case without momentum. For the case without momentum and without STE, the annealing works normally, but the convergence speed is relatively slower than the case without momentum. For the case without clipping, the analog spin proxy does not have any limitation, and it can grow infinitely towards one direction in the solving process. Then if it needs to go towards the other direction in the later solving process, it takes much longer time to accumulate the gradient until it can change its sign and thus largely decreases the solving speed. For STE, momentum, and clipping, they are all common techniques used in BiNN training. While there are more advanced optimizers, such as Adam, and other sophisticated training methods that are widely applied in the field of neural network, which have the potential to be applied to combinatorial optimization, their applicability needs to be further researched due to the different nature of the target problem.

FIGS. 7A and 7B shows the overall experiment set-up. As illustrated in FIG. 7A, a PC is used to control the integrated memristor chip via microcontroller (left), and the printed circuit board (PCB) developed to measure the chip (middle). The optical image of the integrated memristor chip is shown on the right, which consists of three 64×64 1T1M memristor arrays and peripheral circuits including transimpedance amplifiers (TIAs), multiplexers (MUXs), analog-to-digital converters (ADCs) and drivers. CMOS peripheral circuits are taped out by TSMC's 180 nm technology, while the memristor devices are fabricated at backend of line with in-house cleanroom. FIG. 7B shows the optical image of the memristor crossbar array (left); SEM image of the cross-point memristor device (middle) and lateral TEM image of the 50 nm×50 nm Pt/Ta/TaOₓ/Pt memristor device (right).

FIGS. 8A and 8B show the performance of memristor device in the integrated hardware. FIG. 8A shows the DC I-V measurement of 100 Set and Reset cycles demonstrating small cycle-to-cycle variations. The average value is shown by the dark line. FIG. 8B shows the linearity test of different conductance states, demonstrating excellent I-V linearity. FIG. 8C shows the retention test after dividing the entire 64×64 array into 16 subarrays, with each subarray programmed to target a conductance of 0 to 150 μS with a step size of 10 μS. The mean value is shown by the dark line, while the shaded area indicates the interquartile range.

FIGS. 9A and 9B show the impact of the initial λ value and its relationship to maximum eigenvalue of Ising coupling matrix. FIG. 9A shows the Ising coupling matrix. The maximum eigenvalue is 7.76. FIG. 9B shows the success probability of the problem instance in (a) vs. initial λ value. The black dash line shows the position of initial λ value equal to the maximum eigenvalue of Ising coupling matrix.

In the present QPA, the coefficient of the initial Hamiltonian should start with a large enough that the system can be initiated with a function that the ground state can be easily found, i.e. usually a convex function. Since in the updating scheme, the gradient calculated by the binary spin σᵢ is used as an estimator to update the analog proxy spin xᵢ. By replacing binary spin configuration σ in the Ising Hamiltonian with analog spin configuration x, the below is obtained:

$${H}_{system} = \frac{1}{2} λ {\sum }_{i} {x}_{i}^{2} - \frac{1}{2} {\sum }_{i , j} {J}_{i j} {x}_{i} {x}_{j} = \frac{1}{2} ( λ {x}^{T} x - {x}^{T} J x ) = \frac{1}{2} {x}^{T} ( λ I - J ) x$$

In this case, if λI−J≥0, the H_{system} becomes convex and has a ground state when all xᵢ=0. Therefore, to guarantee a convex function, λ should start with a value that is larger than the maximum eigenvalue of Ising coupling matrix J. However, it cannot be too large, as with further larger initial λ, more iterations will be wasted and thus affect the performance. From the above plot, it can be seen that the best performance point locates where initial λ value is a bit larger than the maximum eigenvalue of Ising coupling matrix.

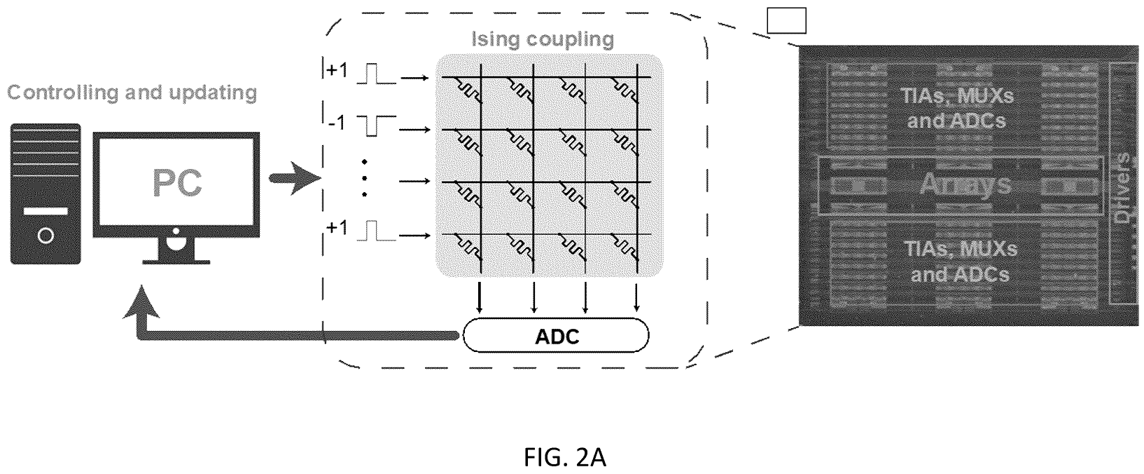

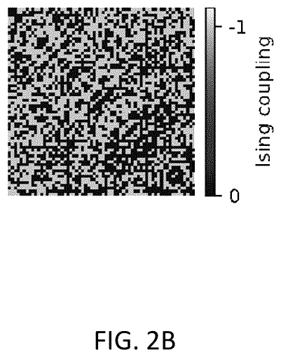

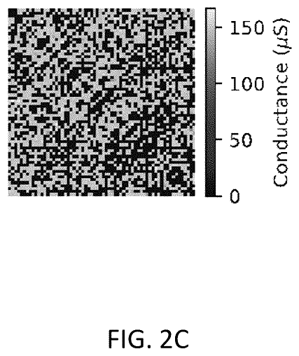

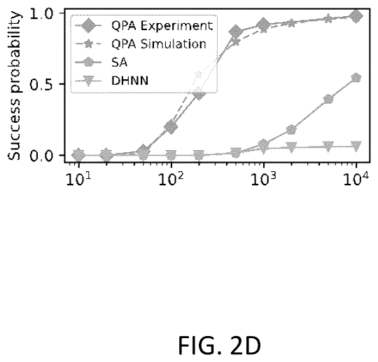

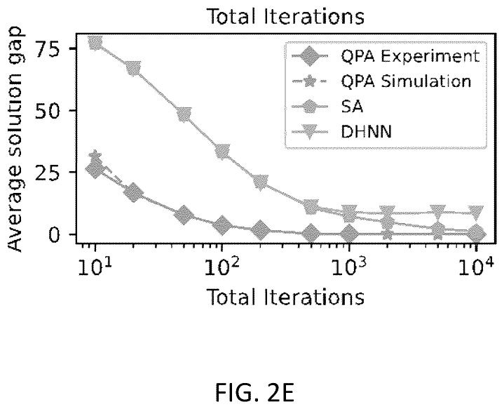

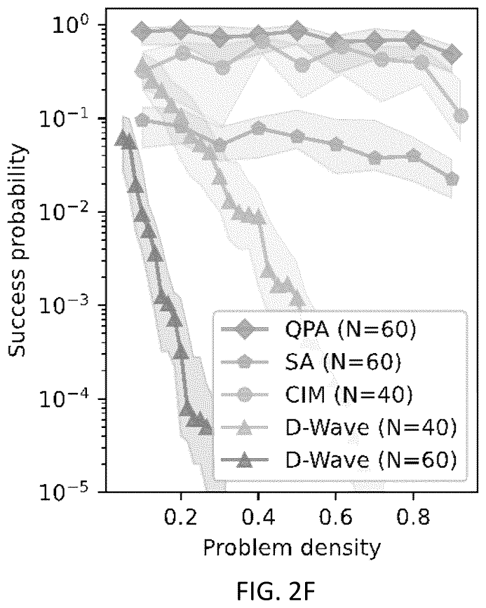

FIGS. 10A and 10B show the impact of step size. FIG. 10A shows a plot of success probability against step size; and FIG. 10B shows a plot of average solution gap against step size. For this plot, the target problem of FIG. 2C is solved with 100 trials. The dash line shows the simulation result with the experimentally validated memristor model, which complies well with the experimental data. From the plot it can be seen that, when the step size is relatively small, increasing it can lead to improved system performance due to each iteration progressing further in the direction of gradient. However, as the step size becomes sufficiently large, the system will diverge. This aligns with the experience in neural network training. In fact, more advanced adaptive changing of step sizes is commonly implemented in the training of neural networks. The selection of optimal hyperparameters including step size, the coefficient of momentum term, is a vast and intricate problem that requires further research in the future.

FIGS. 11A and 11B show the evolution of intermediate values in experimental solving process of weighted Max-Cut problem. FIG. 11A illustrates the evolving process of classical “superposition” (analog spin proxy). FIG. 11B illustrates the evolving process of momentum. During the early stage of the solving process, the classical “superposition” rapidly oscillates between −1 and 1 due to higher impact of initial Hamiltonian, and eventually converges to −1 or 1 to match the binary spin configuration.

FIGS. 12A and 12B show the success probability plots used for calculating TTS of weighted Max-Cut problem. FIG. 12A shows a plot of success probability against problem size for simulated annealing. FIG. 12B shows a plot of success probability against problem size for quantum-inspired annealing.

FIGS. 13A and 13B shows the scaling trend for unweighted Max-Cut problem. FIG. 13A shows a plot of success probability against problem size for simulated annealing. FIG. 13B shows a plot of success probability against problem size for quantum-inspired annealing.

FIG. 13C shows a plot of time to solution against problem size. For each problem size, 20 randomly generated problem instances solved 1000 times with random initial spin configuration. The shaded area in the plot shows interquartile range. The square marker indicates the median.

FIGS. 14A to 14H shows the TSP instance and traveling path comparison. FIG. 14A illustrates the target problem instance solved in this paper. FIG. 14B illustrates the corresponding distance matrix between each city with the unit of km. The distance between each two cities is the shortest distance along the surface of earth and calculated by the coordinates of the city center. FIG. 14C illustrates the spin value matrix representation of the minimum-distance traveling path found by QPA, and FIG. 14D shows its corresponding traveling path in map. FIG. 14E illustrates the spin value matrix representation of the minimum-distance traveling path found by SA, and FIG. 14F shows its corresponding traveling path in map. FIG. 14G illustrates the spin value matrix representation of the minimum-distance traveling path found by DHNN, and FIG. 14H shows its corresponding traveling path in map.

FIGS. 15A to 15C shows the simulation result of solving larger problems in TSPLIB. FIGS. 15A to 15C respectively shows the results of solving burma14 problem, ulysses16 problem and gr17 problem. The Best in the plot represents the best-known solution provided by the library. For each problem, 5000 iterations are conducted for both QPA and SA with 100 trials from random initial states.

### DETAILED DESCRIPTION

In the following description, methods and modification procedures of aptamers as target detectors are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

Various processes will be described below to provide an example of at least one embodiment of the claimed subject matter. No embodiment described below limits any claimed subject matter, and any claimed subject matter may cover processes or systems that differ from those described below. The claimed subject matter is not limited to processes or systems having all of the features of any process or system described below or to features common to multiple or all of the processes or systems described below. It is possible that a process or system described below is not an embodiment of any claimed subject matter. Any subject matter that is disclosed in a process or system described below that is not claimed in this document may be the subject matter of another protective instrument, for example, a continuing patent application, and the applicants, inventors, or owners do not intend to abandon, disclaim or dedicate to the public any such subject matter by its disclosure in this document.

Furthermore, it will be appreciated that for simplicity and clarity of illustration, where considered appropriate, reference numerals may be repeated among the figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures, and components have not been described in detail so as not to obscure the embodiments described herein. Also, the description is not to be considered as limiting the scope of the embodiments described herein.

### Background Regarding Quantum Annealing in Quantum-Inspired Processors

Quantum annealing is an analog computational technique used to solve optimization problems by taking advantage of quantum phenomena. Quantum annealing leverages the principles of quantum mechanics to explore the solution space of a given optimization problem more efficiently than classical methods.

In the context of quantum annealing, spins refer to quantum mechanical entities that can represent binary variables. Each spin can be in one of two states, typically denoted as “up” or “down”, which can be analogous to the values 0 and 1 in classical computing.

The Ising model is a mathematical model used to describe the behavior of interacting spins in a system. Often used in statistical mechanics and condensed matter physics to study phenomena including phase transitions, in the context of quantum annealing, the Ising model is adapted to represent an optimization problem; while the interactions between spins in the Ising model are referred to as Ising coupling. These interactions are represented by coupling coefficients, which determine how strongly spins influence each other. In an optimization problem, these coupling coefficients encode the relationships between variables that need to be optimized.

As opposed to the description of the total energy of a quantum system, in quantum annealing, the Hamiltonian is formulated to encode the optimization problem as an Ising model with certain constraints. It consists of two parts: the “cost function” term, which represents the objective function of the optimization problem, and the “tuning” term, which controls the annealing schedule, which refers to the evolution of the system over time. Initially, the system is prepared in a state where the tuning term dominates, allowing the system to explore the solution space broadly. As time progresses, the tuning term is gradually reduced, while the cost function term becomes more dominant, guiding the system towards the optimal solution.

Throughout the annealing process, measurements are performed on the system to extract information about its state. These measurements provide probabilistic information about the solutions to the optimization problem encoded in the quantum state of the system.

At the end of the annealing process, the system ideally settles into a state that represents a solution to the optimization problem. Measurements can be performed on this final state to extract the solution with a certain probability.

Memristor crossbars and arrays can be used as hardware implementations for Quantum annealing systems. While not inherently quantum devices themselves, they can be employed as part of the classical control and readout systems in a quantum annealing setup.

A memristor is a two-terminal electronic device whose resistance depends on the history of the electric charge that has flowed through it. This unique property allows memristors to store and process information in a non-volatile manner, making them promising candidates for future memory and computing technologies.

Further, in the context of memristors, a crossbar architecture refers to a grid-like arrangement where rows and columns of memristors intersect. Each intersection point represents a memory cell or a computational unit. By applying appropriate voltages to the rows and columns, it is possible to control the state of individual memristors and perform operations such as matrix-vector multiplications, which are fundamental to many computational tasks, including optimization problems.

Memristor arrays are larger collections of memristor crossbars arranged in a grid-like fashion. These arrays can scale up to thousands or even millions of memristors, allowing for massively parallel computation and storage. In the context of quantum annealing, memristor arrays can store and manipulate the coefficients of the Ising model that represents the optimization problem being solved.

While Ising model coefficients encode the relationships between variables in the optimization problem, memristor arrays can be used to store these coefficients efficiently. By setting the resistance of each memristor in the array to a value corresponding to the coefficient it represents, the Ising model can be mapped onto the physical memristor array.

Memristor crossbars can perform computational operations required for quantum annealing, such as matrix-vector multiplications. By applying appropriate voltages to the rows and columns of the crossbar, it's possible to perform dot products between the Ising model coefficients and the current state of the quantum annealing system. This allows for the efficient calculation of the energy landscape of the optimization problem, which is essential for guiding the annealing process.

Memristors can also be used to provide feedback and control signals to the quantum annealing system. For example, they can be used to read out the current state of the quantum system or to adjust the annealing schedule based on the measured performance.

In accordance with a first aspect of the present invention, a quantum-inspired parallel annealing processor for analysing and solving combinatorial optimization problems with increased efficiency is provided herewith, comprising: an integrated memristor chip comprising multiple 64×64 one-transistor one-memristor crossbar arrays; drivers; multiplexers; transimpedance amplifiers; and analog-to-digital converters; and a general computer as a controlling device to the integrated memristor chip.

In this configuration, as a memory operation begins, the drivers can apply appropriate voltages or currents to rows and columns of the 64×64 one-transistor one-memristor crossbar arrays for reading and writing data. Correspondingly, the multiplexers are configured to select and connect specific rows or columns from multiple rows and columns to read or write data. Then, the transimpedance amplifiers convert the current signal from the 64×64 one-transistor one-memristor crossbar arrays to a voltage signal for subsequent signal processing. Further, the analog-to-digital converters are configured to convert the amplified analog voltage signal to a digital signal for digital processing and storage. In one embodiment, the quantum-inspired parallel annealing processor further includes digital logic components configured to perform digital signal processing, control the operations of the entire system, and handle data reading, writing and processing.

The above example demonstrates how the 64×64 one-transistor one-memristor crossbar arrays can be combined with other components to implement a complete memory system. This system can be used in memory storage, and other applications requiring efficient data storage and processing based on the principles of Ising Hamiltonian and spin states and, in the instance of the present invention, for the solution and analysis of combinatorial optimization problems.

In accordance with one embodiment of the present invention, the solving of the combinatorial optimization problems comprises representing the spin configuration as discrete values of 1 or −1; utilizing an analog variable to depict the intermediate spin states akin to a classical “superposition” of the spin; and implementing a time-dependent system Hamiltonian which begins with dominance by the initial Hamiltonian, gradually transitioning towards the Ising Hamiltonian; and employing a straight-through estimator algorithm to update the analog intermediate spin variable based on the system Hamiltonian's gradient computed from the actual spin configuration.

In accordance with another embodiment of present invention, the Ising couplings between each spin pair are stored as analog conductance values in the memristor crossbar to enable single-step in situ calculation of the Ising Hamiltonian's gradient.

### Quantum-Inspired Parallel Annealing (QPA)

Combinatorial optimization problems (COPs) can be reformulated as Ising models in which the spin configuration evolves towards the ground state of a certain energy function known as Ising Hamiltonian, expressed as

$${H}_{Ising} = - {\sum }_{i < j} {J}_{ij} {σ}_{i} {σ}_{j} - {\sum }_{i} {h}_{i} {σ}_{i} = - \frac{1}{2} {σ}^{T} J σ - {h}^{T} σ \qquad ( 1 )$$

where σ={σ₁, σ₂, . . . , σᵢ, . . . , σ_{N}} is the spin configuration vector that encodes the problem's solution, with each component σᵢ being a binary value {−1, 1} representing the two states of spin-up and spin-down. J is a square and symmetric coupling matrix of size N×N, with each element representing the ferromagnetic or antiferromagnetic connections between two spins. h is a local-field term introduced for generality.

In physical quantum systems, the annealing process to solve such a model is accomplished by adiabatic evolution. It starts with a simple Hamiltonian Hᵢₙᵢₜᵢₐₗ, of which the ground state can be easily found (e.g., a transverse field Hamiltonian Hᵢₙᵢₜᵢₐₗ=−Σᵢσᵢ^{x}) and gradually shifts to the Ising Hamiltonian H_{ising}=−Σ_{i<j}Jᵢⱼσᵢ^{z}σⱼ^{z}, expressed as

$${H}_{system} ( t ) = A ( t ) {H}_{initial} + B ( t ) {H}_{Ising} \qquad ( 2 )$$

With A(t) gradually changes from 1 to 0 and B (t) gradually changes from 0 to 1. Ideally, a physical system can always retain the minimum-energy state and thus the system can eventually evolve to the ground state of the Ising Hamiltonian and solve the corresponding COP.

However, in this quantum version of adiabatic annealing, the spin is represented by a Pauli matrix rather than a discrete value, which is not suitable for this current classical analog memristor crossbar to emulate. Therefore, it is adjusted for easier implementation in this analog memristor crossbar and proposed a new classical version of adiabatic annealing, in which the spin σᵢ is represented by a discrete value, either 1 or −1. In order to conduct annealing, an analog variable xᵢ is introduced to represent the intermediate spin states and can be deemed as a classical “superposition” of the spin. The real spin configuration of σᵢ is taken as the sign of xᵢ.

Similarly with the quantum version, a time-dependent system Hamiltonian as below is implemented:

$${H}_{system} ( t ) = λ ( t ) {H}_{initial} + {H}_{Ising} \qquad ( 3 )$$

where, λ(t) is a time-dependent coefficient, which starts with a sufficiently large value and gradually decreases to 0 during the solving process. Hᵢₙᵢₜᵢₐₗ is the initial Hamiltonian and can be arbitrary function the ground state (global minimum) of which can be easily found. In this work,

$${H}_{initial} = \frac{1}{2} {Σ}_{i} {x}_{i}^{2}$$

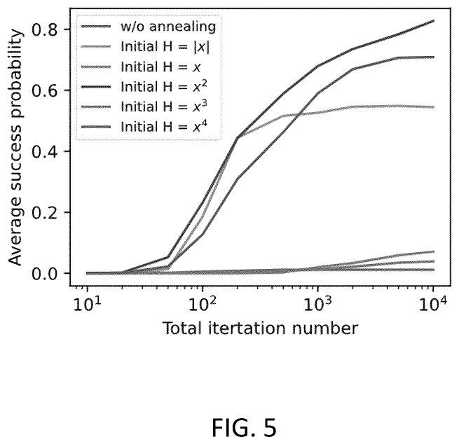

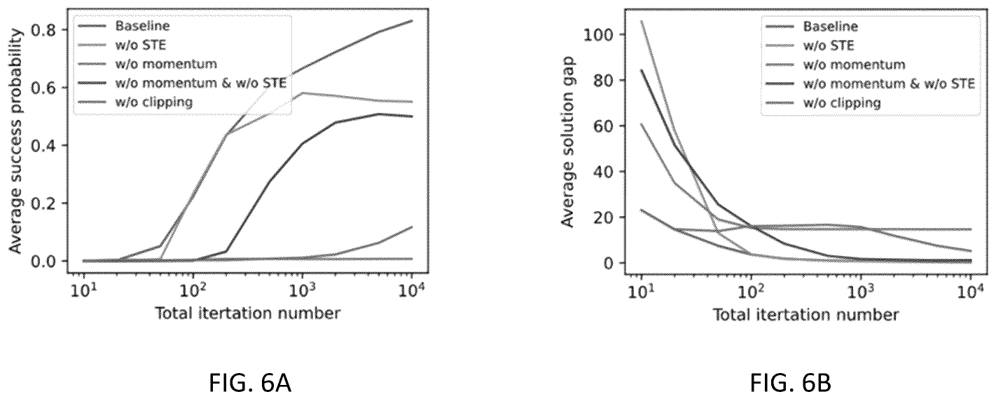

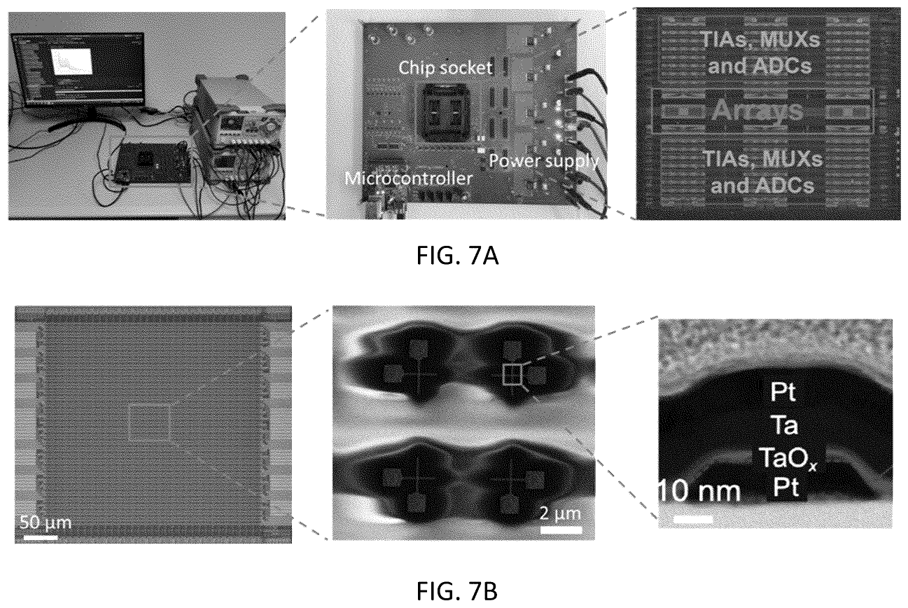

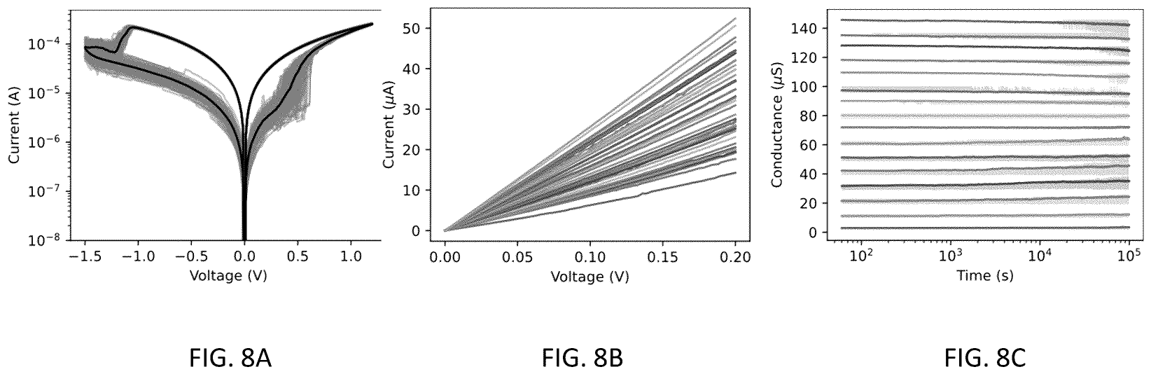

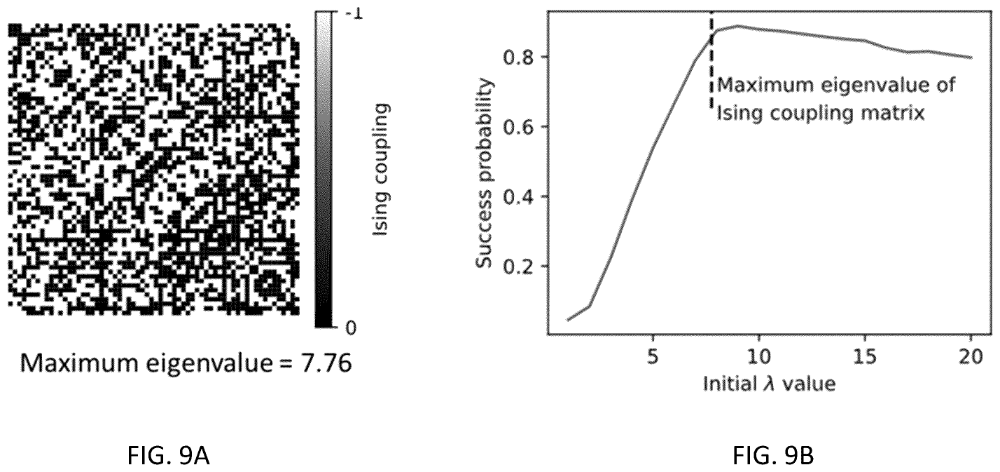

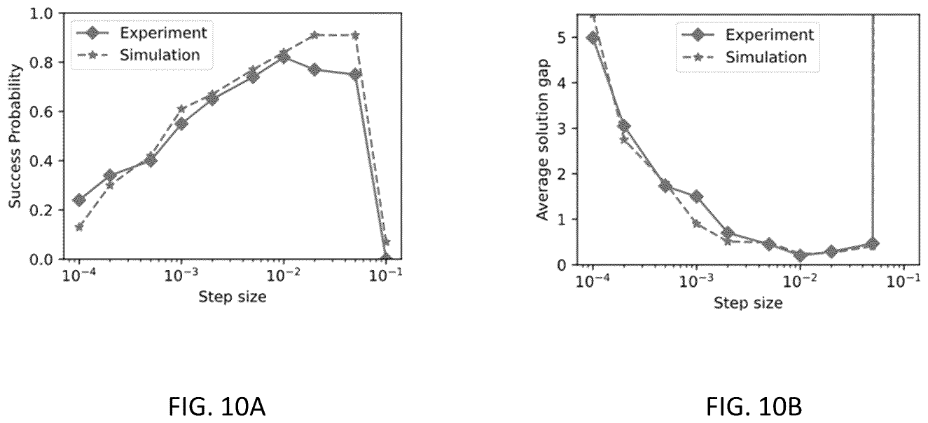

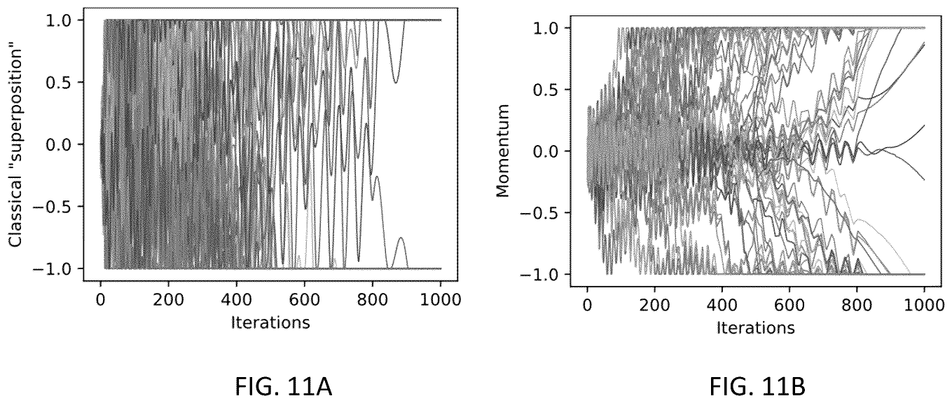

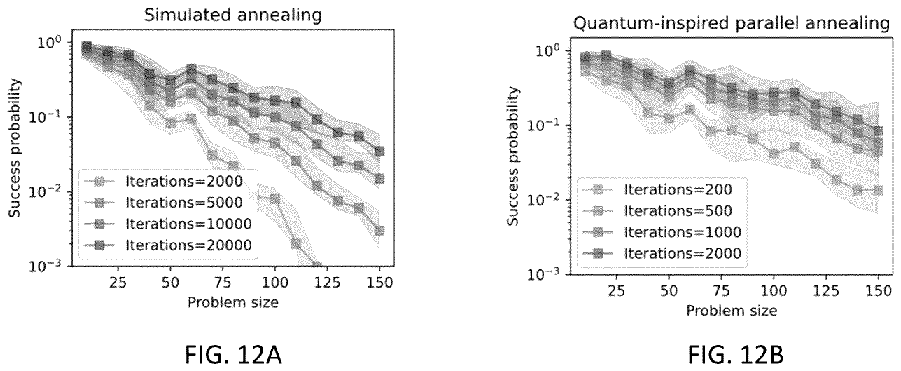

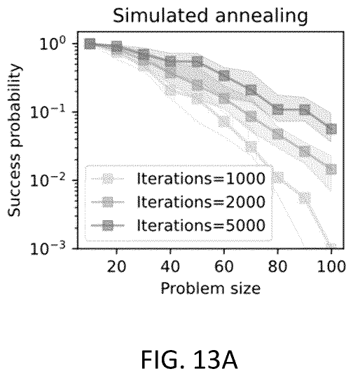

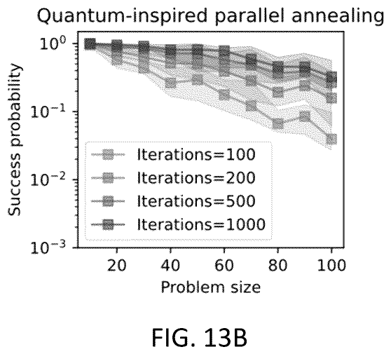

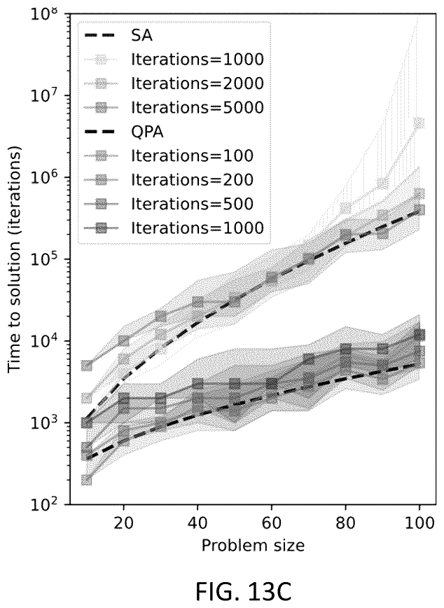

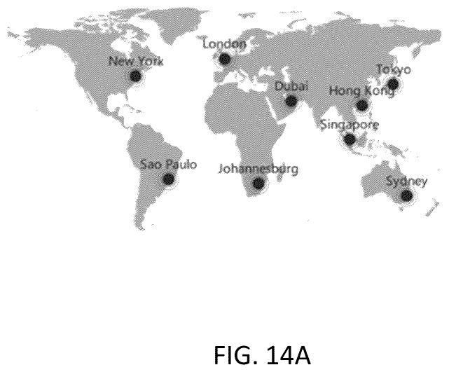

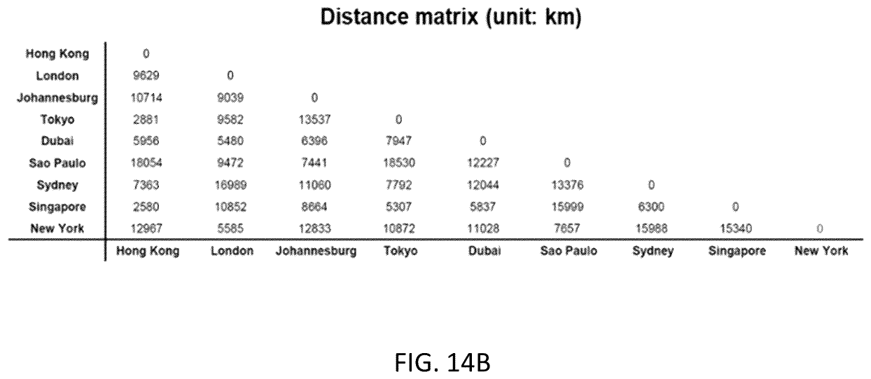

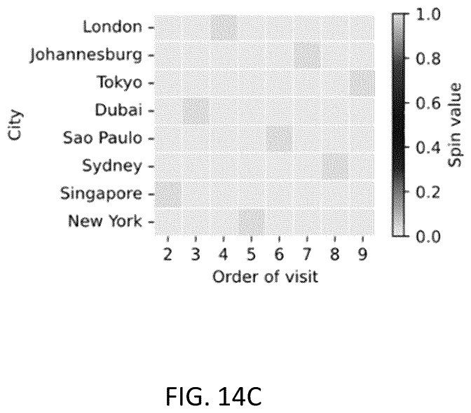

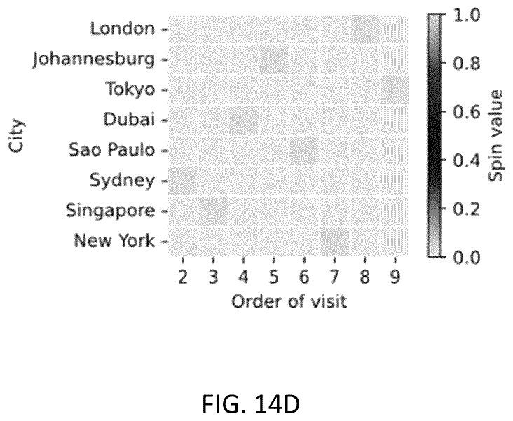

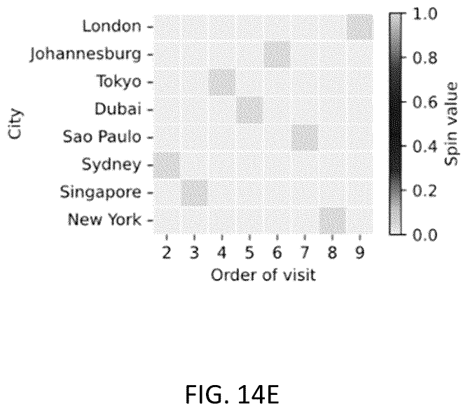

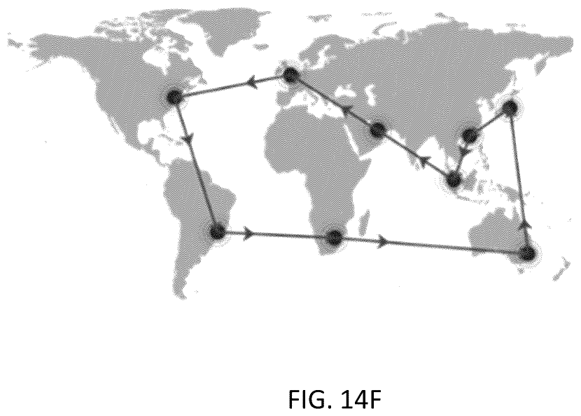

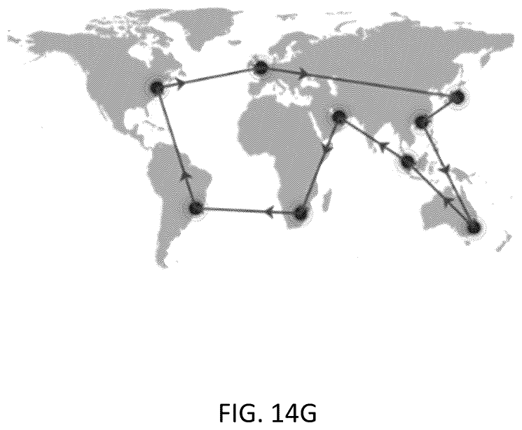

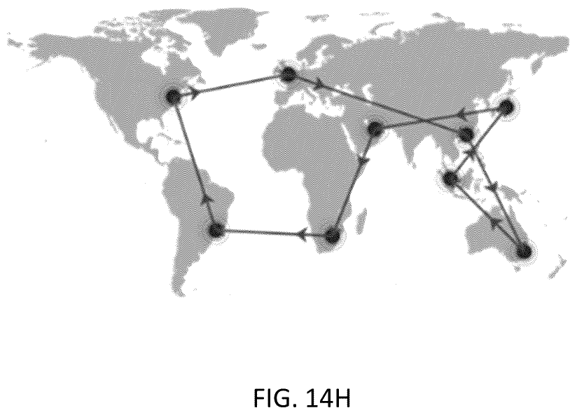

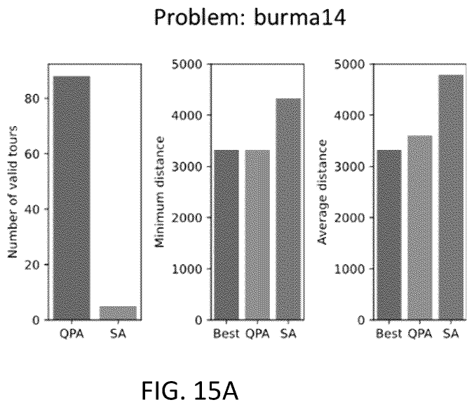

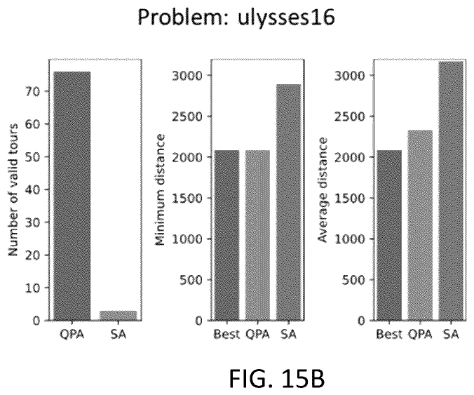

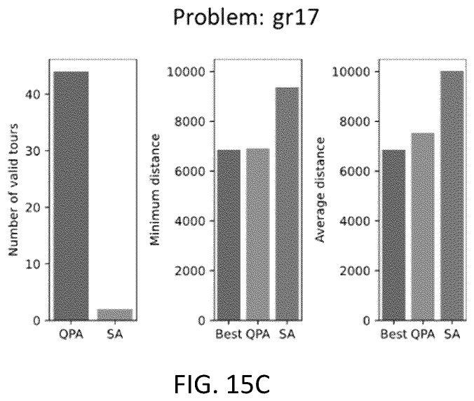

is chosen, one of the simplest convex functions (different choice of Hᵢₙᵢₜᵢₐₗ and their comparisons can be found in FIG. 5). In the solving process, the system is first dominated by Hᵢₙᵢₜᵢₐₗ and will gradually shift to H_{ising}, thus leading to the ground state of H_{ising}. However, unlike real physical systems that naturally tend to evolve towards the lowest energy state during adiabatic evolution, the adiabatic Hamiltonian shift requires the development of an algorithm to enable manual updating of spins and thus lower the energy.

To address this challenge, gradient descent is applied, which is a popular optimization technique used in artificial neural network training, to help the system dynamically evolve into lower system Hamiltonian during adiabatic shift. However, vanilla gradient descent cannot be applied in this case due to the discrete nature of the spin configuration. Each update can only flip the sign of the spin configuration, leading to divergence. To overcome this limitation and inspired by the training of binary neural networks (BiNN), the straight through estimator (STE) algorithm is adopted, which is a modified version of gradient descent that shows great success in the field of neural networks. The key idea behind STE is to introduce a full-precision “latent” weight as a proxy for the binary weight, which is binarized in the forward and backward path to calculate the gradient value. This gradient value is then directly used as an estimator to update the full-precision “latent” weight. Interestingly, the analog intermediate spin variable xᵢ that is introduced earlier to represent the classical “superposition” of the spin states shares similar properties with the “latent” weight and can thus serve as a proxy for the spin.

To implement the STE algorithm in the Ising machine, the analog spin variable x onto the binary domain is first projected using a sign function to obtain the real spin configuration σ. The real spin configuration is then used to calculate the gradient of the system Hamiltonian. Specifically, the gradient is given by

$$gradient = ∇ {H}_{system} = ∇ {H}_{Ising} + λ ( t ) ∇ {H}_{Initial} = - J σ - h + λ ( t ) x \qquad ( 4 )$$

This gradient is then used to update the analog spin proxy x as

$$x ( t + 1 ) = x ( t ) - η * gradient , \qquad ( 5 )$$

where η is the step size. To improve the performance of the algorithm, implemented two commonly used techniques are implemented from stochastic gradient descent in neural network training: clipping and momentum, which are widely used in stochastic gradient descent in neural network training. More techniques from modern neural networks can potentially be applied to further improve performance in the future.

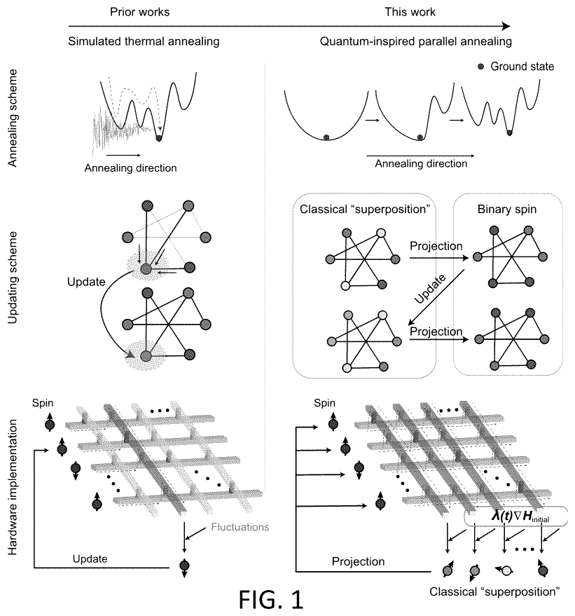

Notably, the gradient-based updating is simultaneously applied with the adiabatic Hamiltonian shift to dynamically find the ground state of the current system Hamiltonian and eventually evolve to the ground state of the Ising Hamiltonian. During the solving process, the Ising couplings between each pair of spins are stored in the memristor crossbar as analog conductance values in an all-to-all manner, which can be used in situ for calculating the gradient of the Ising Hamiltonian in a single step. Therefore, all outputs from the memristor crossbar can be utilized for updating the spins, thus preserving its parallel and analog nature. The key property of this QPA implemented in the analog memristor crossbar and its difference with previous simulated thermal annealing are summarized in FIG. 1.

### Demonstrating QPA in Memristor Crossbar for Max-Cut Problem

To demonstrate the solving ability of the presently presented QPA in memristor crossbar, Max-Cut is chosen as the benchmark problem. Max-Cut is a classical and widely studied NP-hard combinatorial optimization problem, that is commonly used to benchmark Ising machines. The choice is due to its direct map-ability to the Ising model and significant practical applications, which include integrated circuit routing, computer vision and data clustering, etc. The Max-Cut problem involves dividing all vertices V of a given a graph G(V,E) into two sets in a way that cuts the maximum number of edges connecting nodes in different sets. A detailed explanation of the mapping of this problem to Ising model is found in the Methods section. In the implementation, the Ising couplings are stored in the memristor crossbar as analogue conductance values, which are programmed with an iterative write-and-verify approach. The memristor crossbar is then used for computing gradient by performing matrix multiplication in the analog domain, while the part of spin updating is performed in the digital domain (FIG. 2A). All experiments are conducted on the integrated memristor chip of the present invention, which consists of multiple 64×64 one-transistor one-memristor (1T1M) arrays with necessary peripheral circuits including drivers, multiplexers (MUXs), transimpedance amplifiers (TIAs) and analog-to-digital converters (ADCs) (FIG. 2A). In this demonstration, a personal computer (PC) is used for controlling the chip and updating the spins (FIG. 2A). More details about experiment set-up and electrical characteristics of the memristor device can be found in FIGS. 7A-7B and FIGS. 8A-8C.

To start with, a 50%-density (50% of edges are connected) unweighted 64-node Max-Cut problem is used to ensure a fair comparison with recently reported results. The Ising coupling matrix mapped from the problem is shown in FIG. 2B. As only negative Ising coupling is needed in Max-Cut problems and conductance value can only be positive, minus Ising coupling (−J) is converted into conductance values ranging from 0 to 150 μS. After configuring the conductance values into the hardware, the resulting conductance matrix is experimentally read out, as shown in FIG. 2C. The agreement between the mapped and experimentally read-out matrices demonstrated the good performance of this device and hardware platform. Once programmed, the problems are solved using the method described earlier without changing the memristor conductance values.

The problem is then solved by the QPA, the performance of which is compared with that of a naïve discrete-time Hopfield neural network (DHNN) and simulated annealing (denoted as SA for short) with different annealing time (total iterations) in FIGS. 2D and 2E. DHNN is a local search algorithm, which serially update the spins towards lower energy states. The SA implementation here involved adding noises with decreasing amplitude to DHNN, equivalent to the decreasing “temperature” in classical SA implementation and is commonly used in memristor-based implementations. The noise level in SA (the standard deviation of the Gaussian distributed noises) changed linearly from 2 to 0 throughout the iterations. Similarly, for the presented QPA, A changed linearly from 10 to 0, with a fixed step size η=0.01 used for the gradient descent part (further discussion about the choice of λ and step size η can be seen in FIGS. 9A-9B and FIGS. 10A-10B respectively). The results demonstrate that the DHNN without annealing has negligible chance of success because of the local search nature, while the present method clear gave a better solution in terms of both the success probability of reaching the maximum cut value (ground state) and average cut value with the same total iterations than SA. This is owing to the parallelism of the proposed method, which enabled the system to process and preserve more information in a single iteration. Furthermore, the speed of annealing is affected by the change in the total iteration number in this experiment, as the noise level in SA and the coefficient of initial Hamiltonian λ in this QPA changed linearly throughout the iterations. The success probability of SA would eventually reach 100% with sufficient number of iterations, because it has been established that the convergence of SA is guaranteed if the “temperature” changes sufficiently slow. The same is true for adiabatic annealing in quantum systems, where the transfer from the initial Hamiltonian to the Ising Hamiltonian should be sufficient slow (that is obeying the adiabatic evolution rule) to guarantee the system to stay in the ground state. This also might be true for this classical version of adiabatic annealing according to the experiment result that success probability continues to grow with the increasing of total iteration number.

The performance changes with different problem densities are further investigated, and the results are compared with those obtained using other techniques (FIG. 2F). Due to the lack of guaranteed convergence without annealing, DHNN is not compared in this analysis. Owing to experimental hardware resource limitations, the experimentally-validate memristor crossbar model is used, taking into consideration of non-ideal factors in experiments, which has demonstrated high agreement with the experimental data (FIGS. 2D and 2E) for the experiments previously described. The findings show that QPA can achieve a higher success probability than all competitive approaches including SA, the coherent Ising machine (CIM), and the D-Wave quantum annealer. In addition, since the memristor crossbar array is naturally dense and thus has all-to-all connectivity, the proposed system can easily handle problems with varying density.

### All-to-all Connected Weighted Max-Cut Solving

One major distinction between this method and other techniques used in Ising machines is the use of memristor crossbar array to store coupling strength, which offers a unique feature: each cross-point can be programmed to an arbitrary conductance state, enabling the representation of arbitrary coupling strength between any spins with all-to-all connectivity. As practical problems usually require more levels of coupling strength, this feature allows systems based on the present approach to solve such problems without any additional hardware cost, so as to significantly improve both speed and energy efficiency.

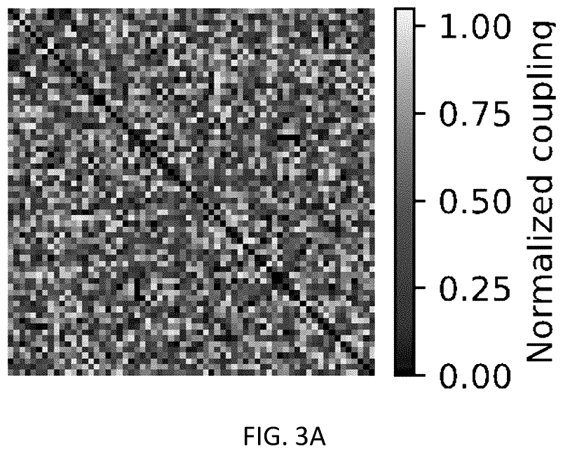

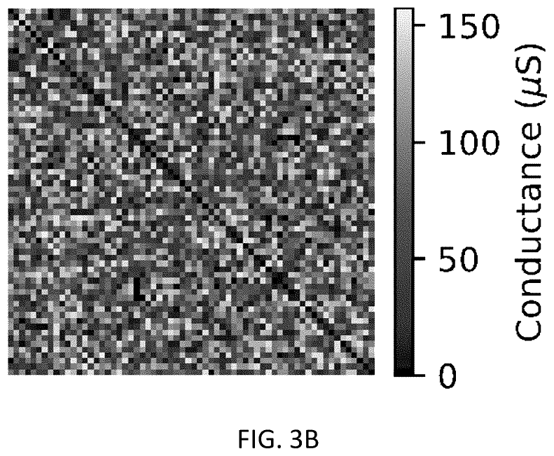

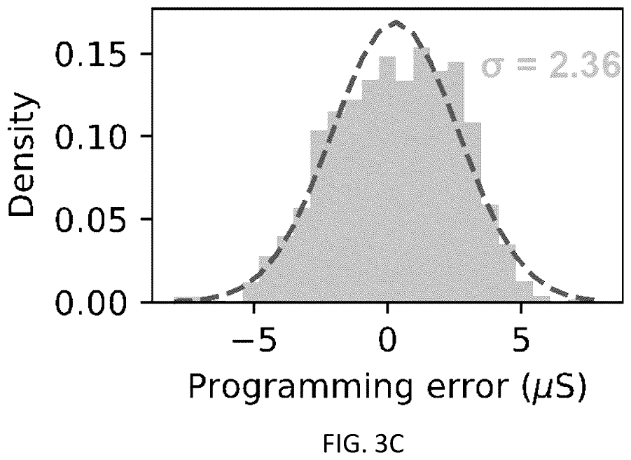

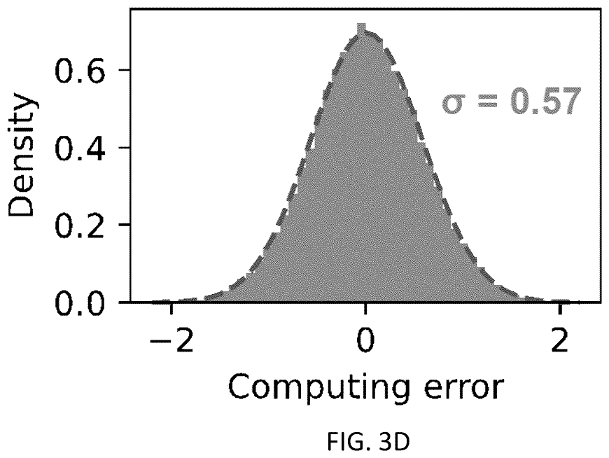

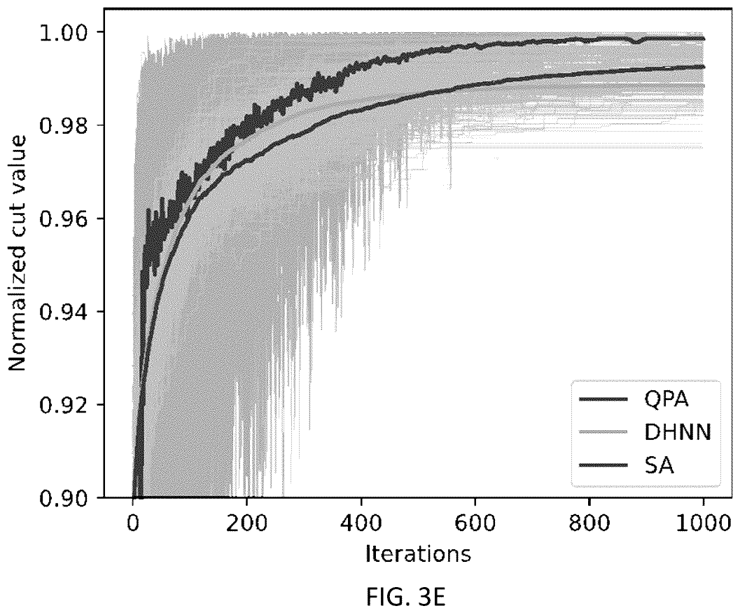

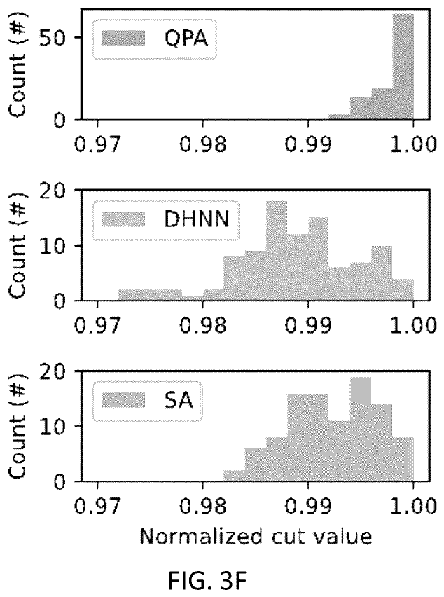

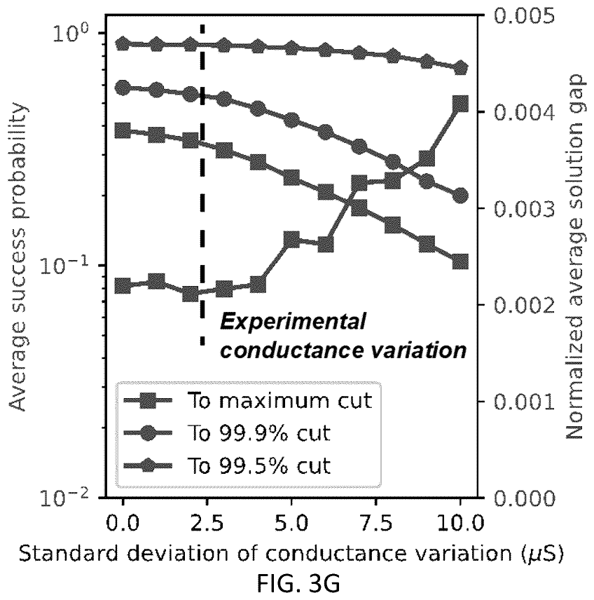

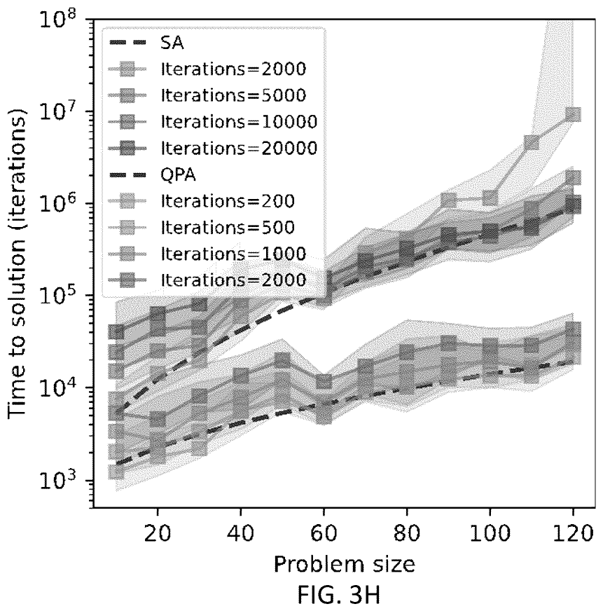

Previous results already certified that this system can be used to solve highly dense Max-Cut problems. In addition to unweighted ones, an all-to-all connected weighted Max-Cut problem is experimentally solved to fully exploit the analog storage and processing capability of memristor crossbar array. First, a random weighted Max-Cut problem is generated, where the weight of each edge randomly is assigned a random 16-bit integer (from 0 to 65,535). The problem is then mapped to a proper conductance range (0 to 150 μS) and programmed onto the memristor crossbar array (FIG. 3B). The programming and computing accuracies are illustrated in FIGS. 3C and 3D, respectively. The results are compared with SA and DHNN. FIG. 3E shows the evolution of the cut value during the solving processing, while the final solution distribution is plotted in FIG. 3F. The evolving process of the classical “superposition” can be observed in FIGS. 11A-11B. Similar to the unweighted Max-Cut problem, this approach obtains a significantly better solution within a certain number of iterations.

As the weight value became an arbitrary value and introduces more energy states, the problem became harder to solve and resulted in the poorer performance of SA and DHNN than when they are used to solve unweighted problems, with limited annealing time (FIGS. 3E and 3F). However, the QPA in the present invention exhibited great performance: 48 out of 100 trials with random initial states finally converge to the true ground state, while neither SA nor DHNN finds the optimal solution even once. Although the variation of memristor inhibited it from being perfectly programmed to a given conductance state, the experimental result confirmed that the current programming accuracy is enough to solve COPs with digital-comparable success probability. Further simulation with different conductance variations is conducted to examine the impact of programming error of memristor crossbar array (FIG. 3G). With a large conductance variation, the success probability of reaching the optimal solution decreases. However, with relatively small conductance variation (0 to 5 μS), the average solution quality, in terms of both success probability (blue line) and the cut values (red line), shows negligible degradation, and the present experimental conductance variation (about 2.36 ρS as shown in FIG. 3C) is far from the value where the accuracy shows noticeable degradation. Additionally, the conductance variation of memristor device can potentially be further reduced with new material stack and denoising techniques to enhance the performance in future systems. For most practical applications scenarios where good-enough sub-optimal solution are accepted, such as 99.5% of the maximum cut value, the analog computing system demonstrates even better tolerance to conductance variation, as shown in almost non-degraded accuracy in FIG. 3G (blue line with pentagon markers), for conductance up to 10 μS (more than four times the present experimental value). This illustrates that the heuristic approach of Ising method is particularly suited for analog computing hardware.

Furthermore, the scaling of time-to-solution (TTS) of different approaches scales with the problem size (FIG. 3H) is investigated. TTS is defined as the time required to guarantee a 99% success probability of reaching the global optimal solution, typically achieved by performing multiple annealing runs and selecting the best result. Therefore, the TTS can be quantitatively calculated as

$$T T S = {T}_{a n n} ⌈ \frac{l g ( 1 - 0.99 )}{lg ( 1 - P )} ⌉ ,$$

where Tₐₙₙ is the annealing time needed for a single run, and P is the success probability of a single run. The success probability used for calculating TTS can be found in FIGS. 12A-12B, while the scaling trend of unweighted Max-Cut problem is shown in FIGS. 13A-13C. Notably, for QPA, the results shown here are from simulation considering experimentally available computing error, while for SA, the results are obtained by defect-free simulation, so the actual improvement over SA is larger than previously reported. The results in FIG. 3G show that the time complexity of both approaches scales exponentially with the square root of problem size N, i.e., TTS=ae^{b\sqrt{N}} where a and b are constants, consistent with previous studies. Although this QPA shows a similar scaling trend to SA, the scaling factors are considerably smaller, indicating a more significant scaling advantage. For example, with a problem size of N=120, the TTS of the proposed method is 46× lower than that of SA. Moreover, by simply extrapolating the curves, the speed-up ratio is expected to increase with problem size.

### Traveling Salesman Problem

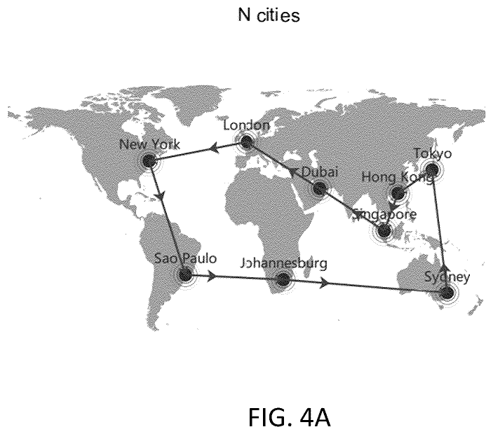

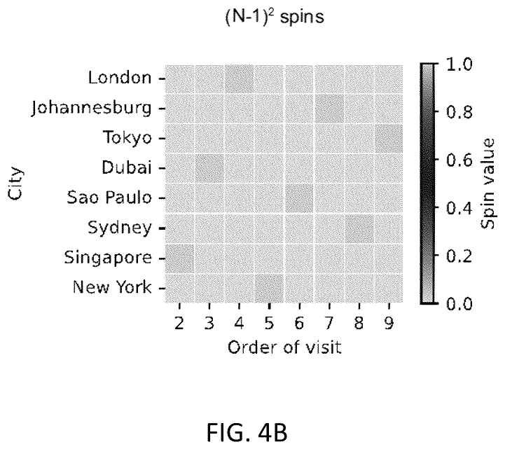

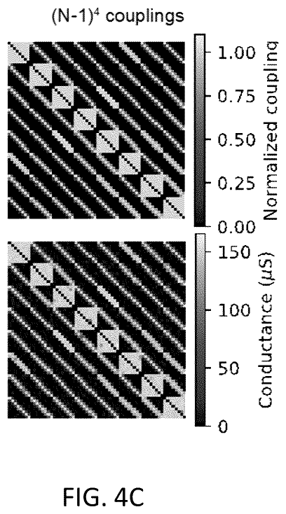

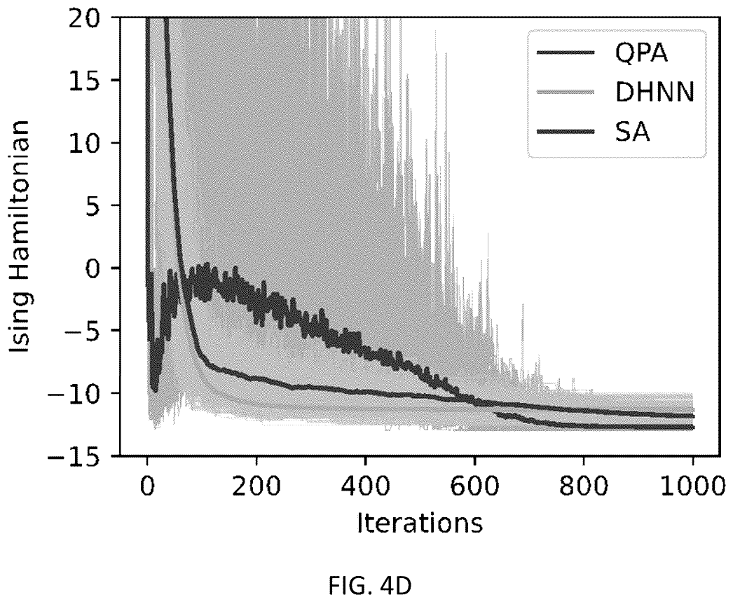

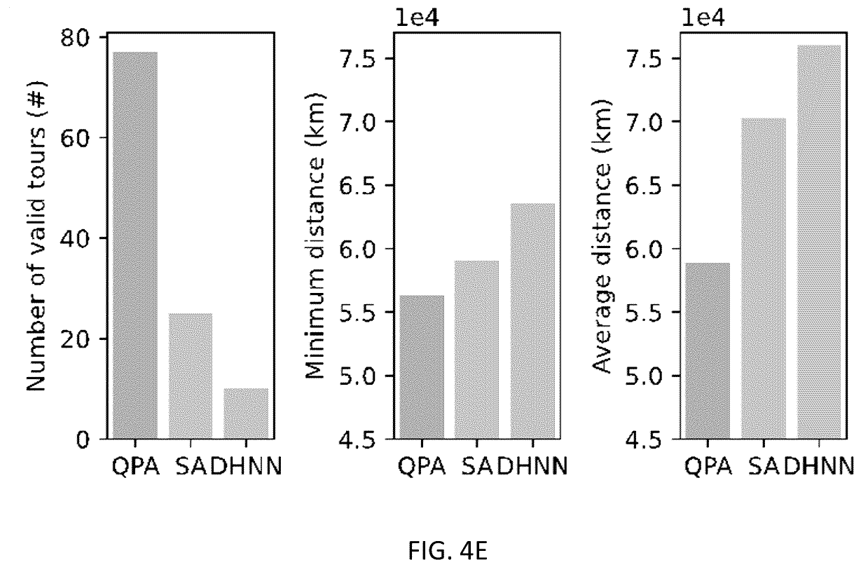

In addition to its capability of solving Max-Cut problems, the memristor-based system of the present invention has the potential to be used for solving other types of combinatorial optimization problems (COPs) due to the universality of the Ising model. To demonstrate this, the traveling salesman problem (TSP) is chosen as another classical COP benchmark task. TSP involves finding the shortest path that visits each city once and returns to the starting city, and has various applications in scheduling and routing problems. To map TSP to the Ising model, (N−1)² spins are used, where N represents the number of cities, and arranged them to a (N−1)×(N−1) matrix with rows representing the cities and columns representing the visiting order (FIGS. 4A-4B). Each row and column should have exactly one spin in the spin-up state to satisfy the constraint that all cities must be visited once and only once. A binary bit formula (either 0 or 1) is adopted for the spin variable, bᵢ, with bᵢ≡σᵢ+1/2, where σᵢ is the spin value, which is either −1 or 1, representing spin-down and spin-up states, respectively. The energy is conveniently phrased using this formula, and the coupling matrix J and bias h are modified accordingly. The detailed process of mapping TSP to the Ising model is presented in the methods section.

FIG. 4C shows the ideal Ising coupling strength and experimental read-out conductance matrix after mapping the target problem in FIG. 4A into conductance and configuring it into the memristor hardware (More details about the target problem can be found in FIGS. 14A-14H). The Ising Hamiltonian evolution using QPA is compared to DHNN and SA in FIG. 4D, similar to the Max-Cut problem. The final solution obtained by different solvers after 1,000 iterations are compared in FIG. 4E. QPA achieved a much higher solution quality with the same number of total iterations, generating more valid tours and finding tours with a smaller minimum and average distance. This demonstrates the effectiveness of this approach in solving TSP. Further scaling simulation results on solving practical problems in TSPLIB can be seen in FIGS. 15A-15C. Moreover, the benefits of the analog property of the memristor device of the present invention enable a significant reduction in the number of device cells needed to solve TSP. For example, to solve a 10-city TSP, the array size can be reduced from 526×200 to 81×81G.

It is worth noting that the mapping method from TSP to Ising model may face scalability issues because the required spin number increases with the square of the number of the cities to visit. The problem can be mitigated by advanced clustering techniques, by breaking down a large problem to several levels of smaller problems. In this case, the solving speed and the solution quality of small problems can be crucial to the entire large problem. Therefore, the analog property of the device, combined with the parallel quantum-inspired annealing of the present memristor-based system for better solution quality, are well suited to such techniques. Moreover, the mixed signal processing of current implementation becomes appealing as it is more compatible to higher level processing that is inevitable for the mapping and clustering.

Table 1 below compares the key properties and performance metrics of various Ising machines, for solving a 100-node dense Max-Cut problem. The key properties include the representation method of spins and couplings, connectivity and precision of couplings, updating and annealing mechanisms, providing basic understanding of each technique. The performance metrics include annealing time, time to solution, power dissipation and energy efficiency. Seven different techniques are compared, including the memristor-based QPA of the present invention, memristor-based Hopfield networks (mem-HNN), phase-transition nano-oscillators (PTNO) based continuous-time dynamic system, CMOS ring oscillator (ROSC) based Ising system, simulated bifurcation machine (SBM) running discrete simulated bifurcation (dSB) on field programmable gate array to represent state-of-the-art digital solver, coherent Ising machine (CIM), D-Wave 2000Q quantum annealer. Details about the estimation breakdown of QPA are shown in Table 2 below.

TABLE 1
Benchmark comparison of QPA implemented in memristor crossbar with other state-
of-the-art Ising machines of solving 100-node 50%-density unweighted Max-Cut problem

| | Present | | | | | | |
|---|---|---|---|---|---|---|---|
| | invention | mem-HNN | PTNO | ROSC | SBM | CIM | D-Wave 2000Q |
| Representation | Digital bits | Digital bits | Oscillator | Oscillator | Digital bits | Coherent light | Superconducting |
| of spins | | | phases | phases | | | qubits |
| Representation | Conductance | Conductance | Capacitance/ | Transmission | Coupling | Coupling | Flux storage |
| of couplings | in memristor | in memristor | resistance | gate | matrix | matrix stored | |
| | crossbar | crossbar | | | stored in | in FPGA | |
| | array | array | | | FPGA | | |
| Connectivity | All-to-all | All-to-all | All-to-all | Sparse | All-to-all | All-to-all | Sparse |
| | | | | (King's | | | (Chimera) |
| | | | | graph) | | | |
| Resolution | Analog | 1 bit | 1 bit | 5 levels | 10 bits | −1 or +1 | 5-6 bits |
| couplings | | | | | | | |
| Update | Synchronous | Hybrid (10- | Synchronous | Synchronous | Synchronous | Asynchronous | Synchronous |
| mechanism | | nodes per | | | | | |
| | | time step) | | | | | |
| Annealing | QPA | Modulating | Second- | — | dSB | Coherent | Quantum |
| scheme | | intrinsic | harmonic | | | computing | annealing |
| | | noises | injection | | | | |
| | | | lock | | | | |
| Annealing time | 400 ns | 1 μs | 10 μs | 50 ns | — | 250 μs | 1 ms |
| Time to | 10.8 μs | 25 μs | 30 μs | >23 μs | 29 μs | 2.3 ms | >10⁴ s (N = 55) |
| solution | | | | | | | |
| Power | 2.3 mW | 16 mW | 2.56 mW | 42 mW | 200 W | >200 W | >25 kW |
| Energy to | 24.8 nJ | 400 nJ | 76.8 nJ | 924 nJ | 5.8 mJ | >460 mJ | >250 MJ |
| solution | | | | | | | |
| Solutions per | 4.03 × 10⁷ | 2.5 × 10⁶ | 1.3 × 10⁷ | 1.08 × 10⁶ | 1.72 × 10² | <2.17 | <4 × 10⁻⁹ |
| second per | | | | | | | |
| watt | | | | | | | |

TABLE 2
Energy and area estimation break down

| Module | Area/μm² | Latency/ns | Energy/pJ |
|---|---|---|---|
| Array | 137.21 | <0.3 | 1.54 |
| Drivers | 275.56 | 0.1 | 0.34 |
| S&H | 3.16 | — | 0.02 |
| MUX | 101.80 | 0.008 | 0.20 |
| ADC | 14250 | — | 2.50 |
| Sum | 14767.73 | — | 4.60 |

To ensure a fair comparison with mem-HNN, the estimations are based on 16 nm technology node. For the analog-to-digital converter (ADC), an 8-bit state-of-the-art successive-approximation-register (SAR) ADC design is used for estimation. For the implementation of QPA, the same working frequency with mem-HNN of 500 Mhz (2 ns for each iteration) is used for benchmarking the time to solution. The power dissipation of this system is estimated by energy consumption for each iteration dividing the time needed for each iteration (4.60 pJ/2 ns) and the result is 2.3 mW.

The performance of solving 100-node 50%-density unweighted Max-Cut problems is compared between the present QPA implemented on memristor crossbar array and other six Ising machines based on different technologies. For the memristor-based QPA of the present invention, the annealing time is set at 200 iterations (400 ns), which results in a success probability of 16%. It takes 27 runs to reach a 99% success probability, resulting in a time to solution of 10.8 μs. The energy to solution is calculated by multiplying the energy needed for a single iteration (4.60 pJ) with the overall iterations needed to reach 99% success probability (5400), resulting in an energy consumption of 24.8 nJ. For memristor-based Hopfield networks (mem-HNN), a hybrid updating scheme is utilized, which updates 10 nodes at a single iteration. To reach optimal time to solution, the annealing time is chosen as 50 updating cycles, where one updating cycle is equivalent to N/10 iterations (N is the problem size), resulting in the annealing time of 1 μs. In addition, this hybrid updating method breaks the guaranteed convergence condition of simulated annealing and might lead to divergence, especially on denser problems with larger connectivity between nodes. More research is needed for the general adaptivity of this hybrid method. For phase-transition nano-oscillators (PTNO) based system, the fully analog property enables the low energy consumption. However, the experimental demonstration is limited to a problem size of N=8, which raises doubts about the effectiveness of the system on larger problems, especially considering of larger parasitic resistance and capacitance for larger problems. For ring oscillator (ROSC) based system, though the annealing time is ultra-fast compared to other techniques, its lack of annealing procedure results in a poor success probability and thus a relatively longer time-to-solution. As success probability of ROSC is not reported, an upper bound value of 1% is used for estimation, according to previous experience on local-search algorithms. This results in the need of 459 runs to reach 99% success probability and the corresponding time to solution of 23 us without considering the overhead brought by comparing such number of solutions. In addition, as ROSC system only supports sparse connection, to solve a dense problem, more spins arc needed for embedding techniques which might further degrade the performance. For simulate bifurcation machine (SBM), the reported time to solution is for solving an all-to-all connected problem with both positive and negative couplings. However, since the difficulty of the problem does not change fundamentally, it is used for estimated comparison purposes here. Additionally, its energy consumption is estimated based on the power dissipation of field programmable gate array (FPGA), which is taken as 200 W in this estimation. For coherent Ising machine (CIM), as the energy consumption is not reported, estimated a lower bound is estimated by considering only the energy consumption of the FPGA part (The power dissipation is assumed to be 200 W), without taking into account of the energy consumption of the optical part. For D-Wave 2000Q quantum systems, the energy consumption is limited by cryogenic cooling, and the speed of solving dense problems is limited by the spare connection.

Therefore, as clearly illustrated in Tables 1 and 2, through implementing the current QPA in memristor crossbar array, the computational speed for the operation is increased with a reduced computer power consumption and dissipation during the operation.

The 100-node unweighted Max-Cut problems is chosen as the benchmark as it is commonly used in other reports, for easier comparison. The QPA implemented on this memristor-based system obtains time to solution of 10.8 μs, which is 2.3× faster than previous state-of-the-art solvers, and obtains energy efficiency of 4.10×10⁷ solutions per second per watt, which is 3.1× greater than previous state-of-the-art solvers. This advantage is primarily attributed to the novel quantum-inspired annealing scheme, which further exploits the parallel, all-to-all connectivity and analog property of memristor crossbar array. It is important to note that the 100-node Max-Cut is not the limitation of memristor-based system, as the state-of-the-art memristor-based in-memory computing macro has 1024×512 devices in a single bank. With a larger array, the advantage brought by synchronous updating can also be enlarged due to the utilization of higher parallelism.

The mixed-signal memristor based approaches, including memristor-based QPA and mem-HNN of the present invention, store and compute the coupling term in the analog domain, while implementing spin updating in the digital domain. In contrast, CIM updates spins in the analog domain and calculates coupling terms in digital domain. Considering that the utilization of quantum mechanics of current CIM demonstration remains unclear and that it can be described accurately by classical dynamics, it is believed that implementing the coupling term in the analog domain might be more efficient at the current stage before CIM showing quantum advantages. This is because the computing complexity of spin updating is usually O(N), with the possibility of reaching time complexity of O(1) if custom parallel digital logic is implemented. On the other hand, the coupling calculation, which CIM implemented in the digital domain, is a VMM operation with a computing complexity of O(N²), making it significantly more compute-intensive than spin updating.

### EXAMPLES

### Clipping and Momentum

During the solving process, after each updating iteration, the analog proxy spin x is clipped between −1 and 1, using the following equation:

$$clip ( x , - 1 , 1 ) = max ( - 1 , min ( 1 , x ) ) \qquad ( 6 )$$

This clipping is a common practice in Binary Neural Network (BiNN) training to prevent the parameter value from growing infinitely, so that a slight change in the value will not have any effect on the result of binarized parameter.

To further increase the convergence speed, a momentum gradient descent is adopted:

$$m ( t + 1 ) = β * m ( t ) - η * gradient \qquad ( 7 )$$

$$x ( t + 1 ) = x ( t ) + m ( t + 1 ) \qquad ( 8 )$$

where β to be the momentum constant, which is set to 0.99 through this paper for simplicity. The momentum m is clipped between −1 and +1 to be prohibited from explosion.

### Mapping Max-Cut to Ising Model

The Max-Cut problem aims to divide all nodes into two subsets. To mathematically represent the problem, sᵢ=1 is used, if the iₜₕ node is in one subset and sᵢ=−1, if iₜₕ node is in the other subset. A is the adjacency matrix with elements defined as Aᵢⱼ=0, if there is no edge between ith and jth nodes and Aᵢⱼ=1, if there is an edge.

The cut number then can be expressed as

$$Cut = \frac{1}{2} {\sum }_{i < j} {A}_{i , j} ( 1 - {s}_{i} {s}_{j} ) \qquad ( 9 )$$

As Σ_{i<j} A_{i,j} is a problem-defined constant, maximizing cut number is equivalent to minimizing −E_{i<j}(−A_{i,j})sᵢsⱼ and thus the problem can be mapped to the Ising Hamiltonian by setting J=−A without the need of local field term h.

### Mapping TSP to Ising Model

To map an N city TSP problem, N spins are required. Each spin is represented in binary bit form (either 0 or 1) and is denoted as b_{v,j}, where v represents the city and j represents the visiting order. The Ising Hamiltonian can be defined by two parts:

$${H}_{A} = A {\sum }_{v = 1}^{N} {( 1 - {\sum }_{j = 1}^{N} {b}_{v , j} )}^{2} + A {\sum }_{j = 1}^{N} {( 1 - {\sum }_{v = 1}^{N} {b}_{v , j} )}^{2} \qquad ( 10 )$$

$${H}_{B} = \frac{B}{2} {\sum }_{u , v = 1}^{N} {D}_{u v} {\sum }_{j = 1}^{N} ( {b}_{u , j} {b}_{v , j - 1} + {b}_{u , j} {b}_{v , j + 1} ) \qquad ( 11 )$$

$$H = {H}_{A} + {H}_{B} \qquad ( 12 )$$

H_{A} imposes constraints to ensure that each city is visited and is visited only once. H_{B} models the summation of the traveling distance of two adjacent visited city, where Dᵤᵥ is the traveling distance between u city and v city. Since each traveling distance is calculated twice, the summation is halved. A and B are coefficients of H_{A} and H_{B}, which determines the contribution of the constrains and traveling distance to the overall Hamiltonian. To balance the validity of the solution and the quality of the solution, B is set to 1 and A is set to max (Dᵤᵥ) throughout this study. Moreover, city 1 is always chosen as the first city to visit and thus reduce the required spin number to (N−1)². This can be understood by fixing the 2N−1 spins to represent city 1 and visiting order 1. This has a constant effect on other spins and only modifies the local field term h, which is added in digital domain in this implementation, and does not change the coupling strength between remaining (N−1)² spins.

### Problem Instance Generation and Optimal Solution

All Max-Cut problem instances used herein are generated by the random module of numpy in python environments with default random seeds. For unweighted Max-Cut problems, a predefined number of “0”'s and “1”s are given first and shuffled by numpy.random.shuffle function to ensure a specific density. For weighted Max-Cut problems, the connection strength is assigned using the numpy.random.randint function by randomly selecting a 16-bit integer (ranging from 0 to 65,535). Since the running time of exhaustive search exceeds 10⁵ s for a single problem with problem size N>50 and continues to scale exponentially with problem size. The optimal solution used in this paper is obtained by running SA for enough long time, i.e., 5Nlog(N) updating cycles (one updating cycle means updating all spins once and corresponds to N² iterations), with 1000 trials for each problem and selecting the best solution among them, to ensure a high confidence of reaching the true optimal solution.

1. A method for combinatorial optimization analysis through parallel annealing, comprising:
providing multiple analog memristor crossbars having a plurality of non-volatile two-terminal memory elements to generate solutions to encoded matrix representations of an optimization problem;
arranging the analog memristor crossbars into one or more array(s) having all-to-all connectivity;
determining the intermediate spin states;
determining the gradients of Ising Hamiltonians based on the spin configuration across each element of the array(s); and
updating the intermediate spin states based on the gradient of the Ising Hamiltonian across each element of the array(s).

2. The method of claim 1, wherein the determining the intermediate spin states comprises:
representing the spin configuration as discrete values through Ising models; and
utilizing an analog variable to depict the intermediate spin states.

3. The method of claim 2, wherein the Ising couplings between each spin pair in the Ising models are stored as analog conductance values in the memristor crossbar arrays.

4. The method of claim 1, wherein the memristor crossbars are further arranged into configurations with transistors in the memristor crossbar array(s).

5. The method of claim 4, wherein the memristor crossbar array(s) comprises a one-transistor one-memristor configuration.

6. The method of claim 1, wherein the memristor crossbar array(s) is further connected to:
drivers;
multiplexers;
transimpedance amplifiers;
analog-to-digital converters; and
digital logics.
